(19) United States
(12) Patent Application Publication
(10) Pub. No.: US 2025/0060423 A1
(43) Pub. Date: Feb. 20, 2025

(54) DETECTION CIRCUITRY

(71) Applicant: MYENERGI LIMITED, Stallingborough, Lincolnshire (GB)

(72) Inventors: Lee Robert Sutton, Stallingborough (GB); Robin Loic Richard, Stallingborough (GB); Seif Aleslam Ibrahim Mahmoud Ahmed, Stallingborough (GB)

(21) Appl. No.: 18/722,886

(22) PCT Filed: Dec. 16, 2022
(86) PCT No.: PCT/GB2022/053274

§ 371 Date: Jun. 21, 2024

(30) Foreign Application Priority Data
Dec. 21, 2021 (GB) 2118618.4

(51) Int. Cl. G01R 31/54; G01R 19/155

(52) U.S. Cl. CPC G01R 31/54; G01R 19/155

(57) ABSTRACT

Voltage and continuity detection circuitry includes a set of terminals for electrically coupling the detection circuitry to an independent electrical apparatus. The set of terminals includes a sensing-input terminal. It further includes a power-output terminal and a reference-voltage terminal, which may be two distinct terminals or one combined terminal. The voltage and continuity detection circuitry further includes a power supply unit for supplying electrical current from the power-output terminal and a voltage sensor for detecting a potential difference between the sensing-input terminal and a reference voltage. The voltage and continuity detection circuitry supports a voltage-detection mode of operation in which it is configured to use the voltage sensor to detect a voltage supplied by the independent electrical apparatus. It also supports a continuity-detection mode of operation that uses the voltage sensor to detect continuity in the independent electrical apparatus. The voltage sensor includes a binary digital output.

This application is entitled to the benefit of, and incorporates by reference essential subject matter disclosed in PCT Application No. PCT/GB2022/053274 filed on Dec. 16, 2022, which claims priority to GB Patent Appln. No. 2118618.4 filed Dec. 21, 2021 which are hereby incorporated by reference in their entireties.

### BACKGROUND OF THE INVENTION

### 1. Technical Field

This invention relates to detection circuitry.

### 2. Background Information

There are situations in which it can be useful to detect the presence or absence of a voltage (i.e. a potential difference), but where a quantitative value of the voltage is not required. Detection circuitry for doing this is known, but can be limited in the range of applications it can support.

Embodiments of the present invention seek to provide more versatile detection circuitry.

### SUMMARY

From a first aspect, the invention provides voltage and continuity detection circuitry comprising: a set of terminals for electrically coupling the detection circuitry to an independent electrical apparatus, wherein the set of terminals comprises a sensing-input terminal and further comprises a power-output terminal and a reference-voltage terminal, wherein the power-output terminal and the reference-voltage terminal may be two distinct terminals or one combined terminal; a power supply unit for supplying electrical current from the power-output terminal; and a voltage sensor for detecting a potential difference between the sensing-input terminal and a reference voltage, wherein: the voltage and continuity detection circuitry supports a voltage-detection mode of operation in which the voltage and continuity detection circuitry is configured to use the voltage sensor to detect a voltage supplied by the independent electrical apparatus by determining the presence or absence of a potential difference between the sensing-input terminal and the reference-voltage terminal; the detection circuitry additionally supports a continuity-detection mode of operation in which the voltage and continuity detection circuitry is configured to use the voltage sensor to detect continuity in the independent electrical apparatus by determining the presence or absence of a potential difference between the sensing-input terminal and the power-output terminal; and the voltage sensor comprises a binary digital output and is configured, in each mode of operation, to output a binary signal from the binary digital output indicative of whether the respective potential difference is determined to be present or absent.

Thus it will be seen that embodiments of the invention provide voltage detection circuitry in which the same voltage sensor and sensing-input terminal can be used both for detecting a voltage from an external device and for detecting electrical continuity in an external device. Such circuitry is therefore more versatile than conventional detectors. Moreover, it may be useful even in contexts where only one of the modes of operation is ever required, since it can be more cost-effective to design, manufacture and deploy one dual-use device implanting such circuitry than to design, manufacture and deploy two separate devices, one for voltage detection and another for continuity detection.

By way of example only, one potential use case is to detect a signal from a domestic electricity meter indicative of whether a low-rate tariff is active or not, and to output a binary logic signal accordingly. Some electricity meters provide such a signal using dry-contact switching, in which a relay within the meter is opened whenever the low-rate tariff is active and closed otherwise, while other electricity meters provide such a signal using wet-contact switching, in which a voltage (e.g. at mains level) is output when the low-rate tariff is active and not otherwise. A device comprising the voltage and continuity detection circuitry as disclosed here can conveniently be configured to detect either signal type (i.e. a dry-contact continuity and a wet-contact voltage) by simply changing its mode of operation. This binary signal may then be used to control the operation of a domestic appliance, such as an electric vehicle (EV) charger, in dependence on whether the low-rate tariff is active or not. This allows the same design of detection device to be connected to support both types of electricity meter, thereby reducing manufacturing and installation costs. However, voltage and continuity detection circuitry embodying the invention is not limited to this particular use case, and may find uses in a range of other settings.

Thus, in some embodiments, the set of terminals may be arranged for electrically coupling the detection circuitry to an electricity meter.

From a second aspect, the invention provides an electrical apparatus comprising voltage and continuity detection circuitry as disclosed herein.

The electrical apparatus may comprise a housing which may house the detection circuitry. The set of terminals may be provided on a face of the housing. The face may be an outer face or it may be recessed. The set of terminals may be provided within one or more sockets, for receiving one or more respective plugs. The apparatus may additionally comprise a binary-output terminal for outputting the binary signal.

The signal from the binary output may be a two-state logic level (e.g. a high or low voltage). In this case the binary output may be a single line. However, the binary output could be more complex, e.g. comprising a parallel or serial port, with the binary signal being encoded (e.g. as pulse-width modulated data) as two states or values out of a larger set of possible states or values.

The electrical apparatus may be a standalone voltage and continuity detection device, or the voltage and continuity detection may be incorporated with additional circuitry for performing one or more further functions that is also part of the same electrical apparatus. The binary output may be used to switch an electrical load in dependence on the output of the voltage sensor. The binary output may be coupled to a relay for performing such switching. The binary output may be communicated to a microcontroller or other digital logic, which may form part of the electrical apparatus or may be separate from it.

Electrical apparatus incorporating the voltage and continuity detection may be, or may comprise, an electrical appliance, which may in some embodiments be a domestic appliance.

The binary digital output may, in some embodiments, be coupled to and/or be arranged to control electric vehicle supply equipment (EVSE), such as an electric vehicle (EV) charger. The electrical apparatus may be EVSE or an EV charger. The EVSE may be arranged to control the charging of an electric vehicle in dependence on the binary digital output. It may be configured to adjust a charge rate in dependence on the binary digital output (e.g. increasing or decreasing the charge rate in response to a change in the binary output).

The binary output may be coupled to and/or control a domestic appliance, an electric heater, or any other electrical apparatus.

In some embodiments, the binary output may be coupled to and/or arranged to control an appliance (e.g. a domestic appliance) that comprises a resistive heating load, such as a domestic storage heater or a domestic electric hot water cylinder. The binary output may be used (e.g. by a controller of, or for, the domestic resistive heating load) to adjust a supply of electrical power to the resistive heating load in dependence on the binary digital output (e.g. increasing or decreasing a voltage and/or current supplied to the load in response to a change in the binary output).

In some embodiments, the binary output may be coupled to and/or arranged to control an appliance that comprises a home energy storage system. The energy storage system may be arranged to receive electrical energy from a domestic wiring circuit and to output electrical energy to domestic wiring circuit. It may store energy in an electrical battery, or a heat battery, or a thermal store, or in any other appropriate way. The binary output may be used to adjust a supply of electrical power to the home energy storage system in dependence on the binary digital output (e.g. increasing or decreasing a voltage and/or current supplied to the home energy storage system in response to a change in the binary output).

In a first set of embodiments, the power-output terminal and the reference-voltage terminal are two distinct terminals. The power-output terminal may be permanently electrically connected to the power supply unit (PSU). The reference-voltage terminal may be permanently electrically connected to a reference voltage line within the detection circuitry.

In a second set of embodiments, the power-output terminal and the reference-voltage terminal are provided as a combined power-output and reference-voltage terminal. In such embodiments, the detection circuitry may comprise a switch that is moveable between a first state (e.g. position) in which the power supply unit is not electrically connected to the combined power-output and reference-voltage terminal, and a second state (e.g. position) in which the power supply unit is electrically connected to the combined power-output and reference-voltage terminal. The detection circuitry may be configured for the voltage-detection mode of operation when the switch is in the first state, and for the continuity-detection mode of operation when the switch is in the second state. The detection circuitry may be configured such that the combined power-output and reference-voltage terminal is electrically connected to a reference voltage line within the detection circuitry when the switch is in the first state, and is not electrically connected to the reference voltage line when the switch is in the second state. The switch may be a double-throw switch.

The switch may be arranged for mechanical actuation. It may be arranged for manual actuation, e.g. by a human operator. It may comprise a moveable part (e.g. a rocker or rotary knob) for manual operation. It may be arranged for actuation by a mechanical feature of a plug, such as a plug for coupling the external electrical apparatus to one or more terminals of the set of terminals. The mechanical feature may be a feature of the shape of the plug, which may be constant. It may be a protrusion or a recess. The switch may be arranged to be in the first state when a plug having the mechanical feature is coupled to a terminal of the set of terminals (e.g. when the plug is inserted in a socket of the detection circuitry), and to be in the second state when a plug not having the mechanical feature is coupled to the terminal (e.g. when inserted in the same or a different socket of the detection circuitry). This can advantageously prevent inadvertent actuation of the switch (e.g. by a user), and consequent malfunction or damage, by allowing an installer to fit the appropriate design of plug for a given use case.

The power supply unit (PSU) is preferably arranged to output direct-current (DC) from the power-output terminal. The PSU may be configured to receive power from an electrical power source located within the detection circuitry or located externally to the detection circuitry and electrically coupled to the detection circuitry. The PSU may be configured to receive alternating-current (AC) or DC power. The PSU may be configured to receive mains electrical power, which may be a domestic mains supply. It may be configured to receive AC power at a voltage of between 100V and 130V (optionally between 110 V and 120 V) or between 200V and 260V (optionally between 220 V and 240 or 250 V). The PSU preferably comprises an isolator for galvanically isolating the power-output terminal from the electrical power source. This can protect the power source from wiring faults in the independent electrical apparatus. The isolator may comprise a transformer. The isolator is preferably a DC-DC converter. It may be a solid-state isolated switched-mode DC-DC converter.

The detection circuitry (e.g. the PSU) is preferably configured to prevent current from flowing into the detection circuitry through (i.e. from) the power-output terminal. It may comprise a diode arranged to prevent such current flow.

The detection circuitry (e.g. PSU) may be configured to attenuate (partially or completely) current from flowing through the power-output terminal in response to an attenuation condition being met (i.e. and not to attenuate as much or at all when the condition is not met). The condition may depend on the level of the current and/or a duration of current flow—e.g. it may comprise the current being above a threshold level for a predetermined time. The condition and/or the attenuation may be for current flowing into the detection circuitry or out of the detection circuitry or both. The detection circuitry preferably comprises a positive temperature coefficient (PTC) device arranged to varyingly attenuate current from flowing through the power-output terminal. The PTC device may provide over-current protection by operating as a temperature-dependant resistor that is active only when a fault is present, such as if the detection circuitry is incorrectly wired to the external apparatus. This can help protect the detection circuitry from excessive current flow. It may also attenuate (partially or completely) current from flowing into the detection circuitry from the power-output terminal, e.g. if a reverse-flow diode that would otherwise prevent such current flow is overloaded.

In less preferred embodiments, excess current protection may be provided by a fuse, or the detection circuitry may comprise a detector configured to detect current flow above a threshold level or to detect a temperature above a threshold level (e.g. a temperature of a PTC device) and to disconnect some or all of the detection circuitry from the power-output terminal in response to such detection. In two-terminal embodiments, the detector may be configured to switch the switch from the second state to the first state in response to such a detection. It may further be configured to latch the switch in the first state until a manual action is taken to unlatch the switch. In this way, normal actuation of the switch, e.g. by insertion of a plug shaped to activate the continuity-detection mode of operation, can be prevented until a human operator (e.g. an electrician) has checked the safety of the installation. The switch may be a latching single-pole-double-throw thermo-mechanical switch with a manual reset.

The detection circuitry is preferably configured to power the voltage sensor independently of any external voltage applied to sensing-input terminal. The voltage sensor may be powered by a power supply independently from the PSU, but in embodiments in which the PSU comprises an isolator for providing an isolated power supply, the detection circuitry is preferably arranged to power at least part of the voltage sensor from the isolated power supply. This can conveniently provide galvanic isolation to all of the set of terminals, so as to further protect the detection circuitry from faults.

The detection circuitry may be configured for electrically connecting the reference-voltage terminal (permanently or switchably) to a reference voltage provided by the isolated power supply. Where the isolated power supply is a DC supply, the reference voltage may be at zero volts.

The voltage sensor preferably comprises a resistor arranged to resist current flow into the voltage sensor through the sensing-input terminal.

The voltage sensor is preferably arranged to prevent current from flowing out of the detection circuitry from the sensing-input terminal. It may comprise a diode arranged to prevent such current flow.

The voltage sensor preferably comprises an isolator for galvanically isolating the binary digital output from the sensing-input terminal. The isolator may be current-driven but is preferably voltage-driven. It may be an opto-coupler, but is preferably a digital isolator. A digital isolator can advantageously provide a high impedance to the sensing-input terminal, to avoid drawing excessive current through the sensing-input terminal from the external electrical apparatus (which could be an externally supplied voltage or which could be provided by the power supply unit, depending on the mode of operation). This can avoid causing an externally supplied voltage to drop due to excessive current flow. The binary digital output may be an output of the digital isolator. The digital isolator may be powered by the isolated power supply of the PSU on its positive side. It may be configured to receive power, on its isolated side, from a further electrical power source located within the detection circuitry or located externally to the detection circuitry and electrically coupled to the detection circuitry.

The voltage sensor is preferably configured for rectifying an input voltage at the sensing-input terminal (i.e. converting AC to DC). It may be configured for reducing (e.g. clipping) an input voltage received at the sensing-input terminal to a lower level (e.g. to below 10V), at least when the voltage at the sensing-input terminal is above a threshold level. It may comprise a Zener diode for reducing the voltage at the sensing-input terminal. This can prevent damaging a digital isolator.

The voltage sensor is preferably configured to sense AC and DC voltages. It is preferably configured to detect AC voltages across a range of frequencies of up to 1 kHz or higher and/or down to 50 Hz or lower. It is preferably configured to detect AC voltages up to 1000V (RMS) or higher and/or DC voltages up to 1500V or higher, as a well as lower voltages (e.g. 24 VDC, 48 VDC, 110 Vrms, 230 Vrms, etc.).

Features of any aspect or embodiment described herein may, wherever appropriate, be applied to any other aspect or embodiment described herein. Where reference is made to different embodiments or sets of embodiments, it should be understood that these are not necessarily distinct but may overlap.

### BRIEF DESCRIPTION OF THE DRAWINGS

Certain preferred embodiments of the invention will now be described, by way of example only, with reference to the accompanying drawings, in which:

FIG. 1 is a schematic drawing of a three-terminal voltage and continuity detector embodying the invention;

FIG. 2 is a schematic drawing of the three-terminal detector coupled to an external voltage source;

FIG. 3 is a schematic drawing of the three-terminal detector coupled to an external switch;

FIG. 4 is a schematic drawing of a two-terminal voltage and continuity detector embodying the invention;

FIG. 5 is a schematic drawing of the two-terminal detector coupled to an external voltage source;

FIG. 6 is a schematic drawing of the two-terminal detector coupled to an external switch;

FIG. 7 is a schematic drawing of a first plug, for detecting external continuity, before (top) and after (bottom) being inserted into a variant two-terminal detector; and

FIG. 8 is a schematic drawing of a second plug, for detecting an external voltage, before (top) and after (bottom) being inserted into the variant two-terminal detector.

FIG. 9 is a circuit diagram of the three-terminal detector; and

FIG. 10 is a schematic drawing of the three-terminal detector coupled to a differential-tariff electricity meter.

### DETAILED DESCRIPTION

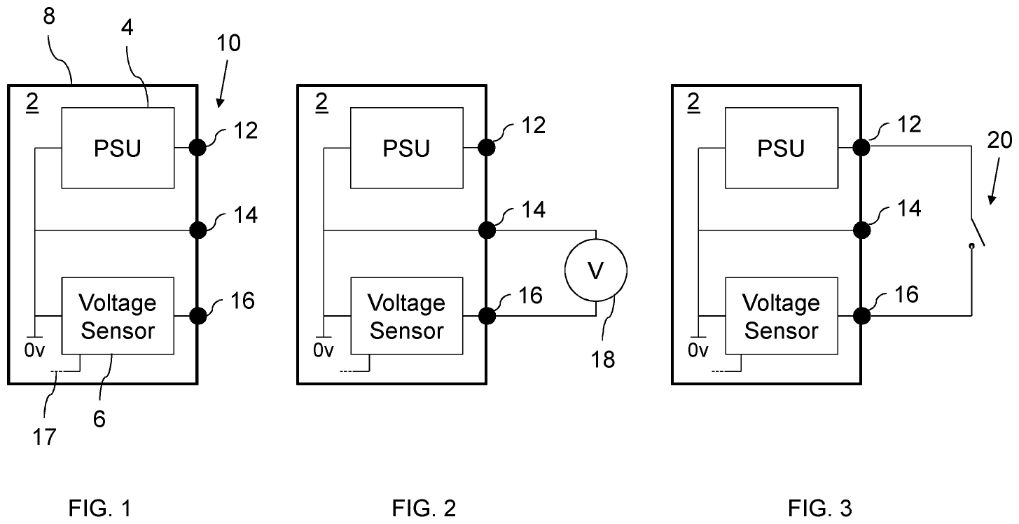

FIG. 1 shows a three-terminal voltage and continuity detector 2. It contains a power supply unit (PSU) 4 and a voltage sensor 6 within a housing 8. There is a set of three electrical terminals 10 arranged on a face of the housing 8 (which may be on an outer surface, or on a face of a recessed socket), for connecting the detector 2 to an external electrical device by a lead. The three terminals 10 are a power-output terminal 12, a reference-voltage terminal 14, and a sensing-input terminal 16. The power-output terminal 12 is electrically connected to the PSU 4. The sensing-input terminal 16 is electrically connected to the voltage sensor 6. The reference-voltage terminal 14 is connected to an isolated voltage reference line, nominally held at zero volts (0V). The PSU 4 and voltage sensor 6 also have electrical connections to the 0V reference line.

The voltage sensor 6 is arranged to detect the presence or absence of a wide range of alternating-current (AC) and direct-current (DC) voltages. It has a binary digital output line 17 (i.e. a single wire) on which it outputs a logic high signal on the output line 17 when it detects a positive potential difference, and a logic low signal otherwise. The binary output line 17 may be coupled to other internal circuitry (not shown) located within the same housing 8, or it may connect to an electrical output terminal on a face of the housing 8, for connecting the detector 2 to external circuitry. Such internal or external circuitry may include a microcontroller or other digital logic configured to act in dependence on the state of the binary output 17—e.g. to activate or deactivate a load. In some embodiments, the output line 17 may be connected directly or indirectly (e.g. via a relay) to one or more domestic appliances, such as electric vehicle supply equipment (EVSE), an electric water heater, a space heater, a washing machine, etc.

FIG. 2 shows the detector 2 arranged to detect the presence or absence of an external voltage from an external voltage source 18. The voltage source 18 is connected across the reference-voltage terminal 14 and the sensing-input terminal 16. The power-output terminal 12 is left disconnected. In this mode of operation, the voltage sensor 6 can thus detect whether the voltage source 18 is active (i.e. creating a potential difference between these terminals 14, 16) or inactive (i.e. not supplying a potential difference), and the binary output on the line 17 will represent the presence or absence of the external voltage.

FIG. 3 shows the detector 2 arranged to detect the presence or absence of continuity of an external switch 20 (i.e. whether the switch 20 is open or closed). In this mode of operation, the external switch 20 is connected between the power-output terminal 12 and the sensing-input terminal 16. The reference-voltage terminal 14 is left disconnected. The PSU 4 maintains the power-output terminal 12 at a higher voltage than the 0V reference, and thus outputs an electrical current through the switch 20 when the switch is closed, which is received by the voltage sensor 6. No current flows when the switch 20 is open. The voltage sensor 6 can thus detect the presence or absence of continuity through the external switch 20, and the binary output on the line 17 will represent the state of the switch 20.

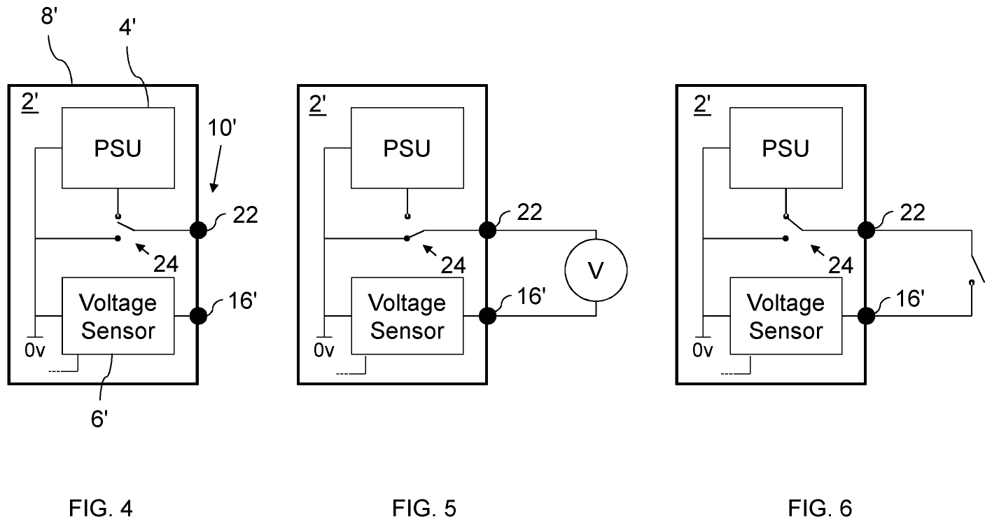

FIGS. 4, 5 and 6 show a variant detector 2′ in which the set of terminals 10′ contains only two terminals: a sensing-input terminal 16′ and a combined power-output and reference-voltage terminal 22. The combined power-output and reference-voltage terminal 22 is connected to a double-throw switch 24 within the detector 2′ that electrically couples the combined terminal 22 to the PSU 4′ when the switch 24 is in a first position (i.e. such that the terminal 22 operates as a power-output terminal), and to the 0V reference line when the switch 24 is in a second position (i.e. such that the terminal 22 operates a reference-voltage terminal). In other regards, the two-terminal detector 2′ operates in the same manner as the three-terminal detector 2.

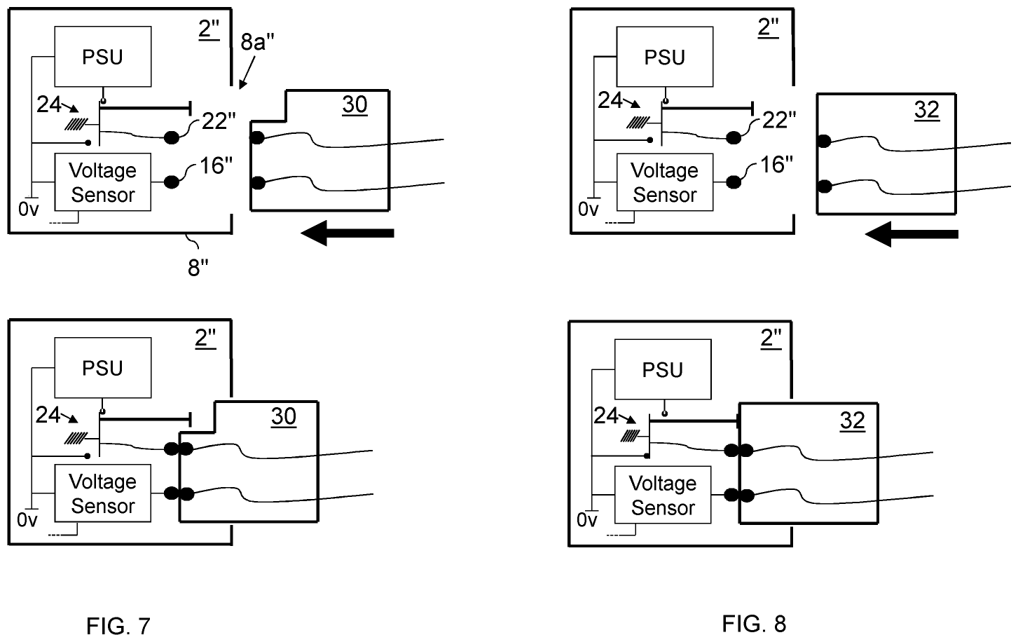

The switch 24 may be a mechanical switch or an electrical switch. It could be controlled by a physical switch on a face of the detector housing 8′, e.g. for a human installer or operator to throw. However, in some embodiments it is controlled in dependence on the physical structure of a plug that is inserted into the detector 2′. An example of such an arrangement is shown FIGS. 7 and 8.

FIGS. 7 and 8 show a two-terminal detector 2″ that has a socket 8a″ defined in its housing 8″. The socket 8a″ is shaped to receive either of two different designs of plug 30, 32. The first plug 30 has a recess in its casing that causes the detector 2″ to operate in the continuity-detection mode of operation. The second plug 32 lacks the recess and instead sets the detector 2″ to operate in the voltage-detection mode of operation. The switch 24 is a sprung double-throw push switch, which is positioned so that the first plug 30 does not depress the switch 24 due to the recess in the plug 30, while the second plug 32 does depress the switch 24. When the switch 24 is depressed after a plug 32 is inserted, as shown in the bottom half of FIG. 8, the combined power-output and reference-voltage terminal 22″ is connected to the 0V reference for detecting an external voltage. When the switch 24 is not depressed after a plug 30 is inserted, as shown in the bottom half of FIG. 7, the combined power-output and reference-voltage terminal 22″ is connected to the PSU for detecting continuity.

This design allows an installer (e.g. an electrician) to provide a lead that has the appropriate plug 30, 32 for an intended mode of operation of the detector 2″ and thereby prevents a user (e.g. a householder) from accidentally reconfiguring the detector 2″ to operate in the wrong mode of operation, which could cause it not to operate correctly and might potentially damage the detector 2″. This arrangement is therefore less prone to user error than a manual switch on the exterior of the detector 2″.

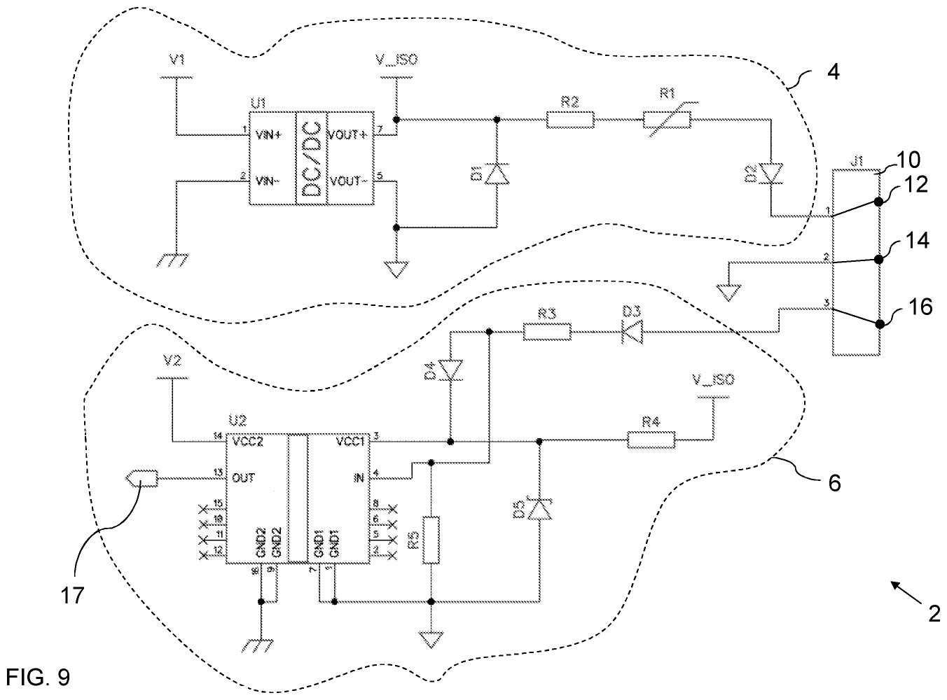

FIG. 9 provides an exemplary design for the circuitry within a three-terminal detector 2. It includes various mechanisms in order to protector the detector 2 from external wiring faults, as explained below.

The PSU 4 is powered by a DC supply which may be generated within the detector 2 or received from outside the detector 2. The supply is passed through an isolating DC-DC converter U1. This isolates the power-output terminal 12 from the DC supply in order to protect the supply from external wiring faults. A diode D1 is connected in parallel across the outputs of the converter U1 in order to prevent negative polarity of the PSU 4. Connecting in series after the output are a resistor R2, a positive temperature coefficient (PTC) thermistor R1, and a second diode D2, followed by the power-output terminal 12.

The second diode D2 protects the PSU 4 from current flow from the power-output terminal 12 to the PSU 4. However, as the detector 2 is designed to support sensing of large external voltages (e.g. 230V AC), special attention is needed as DC and 230V AC could potentially be connected together in a fault situation. In this scenario, large current flows could be seen, potentially damaging the protection diodes in the voltage sensor 6 and the PSU 4. Using a constant large value resistor to limit current is not appropriate as it would prevent the voltage sensing circuit 6 from being able to function correctly. Instead, the resistor R2 is kept to a low resistance value and the PTC R1 provides over-current protection by operating as a temperature-dependant resistor that is active only when a fault is present. It has a low resistance at normal operating temperatures but a very high resistance (e.g. in the order of hundreds of kQs to MQs) at higher temperatures. In a case of a fault (e.g. an external voltage being connected to the power-output terminal 12), a high current could flow through the circuit which could be damaging over extended periods of time, but only a couple of seconds are enough to generate enough heat through the PTC R1 for it to reach its temperature threshold where its resistance increases enough to dramatically reduce the faulty current, putting the whole circuit in a stable, safe condition. The provision of a PTC allows for system stability, as the overvoltage can be left connected for an extended time. Also, unlike a fuse, the PTC R1 automatically resets and is maintenance free. It can also be incorporated conveniently as a TH or SMD package.

The reference-voltage terminal 14 is connected to the isolated 0V level output from the DC-DC converter U1 (indicated by the downward-pointing triangles in FIG. 9).

The voltage sensor 6 is powered by the isolated output of the DC-DC converter U1. It receives an input from the sensing-input terminal 16, which may be AC or DC and cover be from a wide range of voltages. In particular, the voltage sensor 6 can safely detect Extra Low Voltage (ELV) levels of up to 50V AC (RMS) and up to 120V DC ripple-free, but also Low Voltage (LV) levels of up to 1000V AC (RMS) and up to 1500V DC, as defined by IEC 61140.

The voltage sensor 6 is built around a digital isolator U2 which is powered by the isolated supply on the positive side and by a separate low voltage supply on the isolated side. This separate low voltage supply may, as with the isolated supply, be generated within the detector 2 or received from outside the detector 2. The digital isolator U2 is well-suited to the purpose of isolating the separate low voltage supply and digital output line 17 from the voltage-input terminal 16, while also being high impedance and voltage-driven (in contrast to a current-driven opto-coupler). This use of a digital isolator U2 enables a high-impedance sense path, meaning that no current is drawn from the sensing-input terminal 16 for the purpose of the detection, allowing a low-loss detection through a wide input voltage range. However, the CMOS input of the isolator U2 should be protected against reverse polarity and over-voltage.

Any current received at the voltage-input terminal 16 must thus pass through a half-wave rectifying diode D3 and a current-limiting series resistor R3, before being provided as input to the digital isolator U2. The input is protected against high input voltages by a diode D4 that clips the input signal. The input is also connected to the isolated 0V level through a large resistor R5, which ensures the input is tied to 0V, rather than floating, when the voltage-input terminal 16 is disconnected.

The VCC input to the positive side of the digital isolator U2 is derived from the isolated supply, but is taken from between a resistor R4 and a Zener diode D5 arranged in series between the isolated supply and 0V levels, which act to limit the voltage across the digital isolator U2 e.g. to a lower voltage level which is appropriate for the digital isolator supply voltage rating.

In this example, the three terminals 10 are presented for external electrical connection by a three-way terminal block. However, in other embodiments different terminal couplings could be provided, e.g. for spring, screw or solder connections.

The same circuit can also be readily adapted for use in a two-terminal detector, by wiring a double-throw switch between the line to the power-output terminal 12 and the line to the reference-voltage terminal 14, and coupling the output of the switch to a combined power-output and reference-voltage terminal 22. The sensing-input terminal 16 need not be modified.

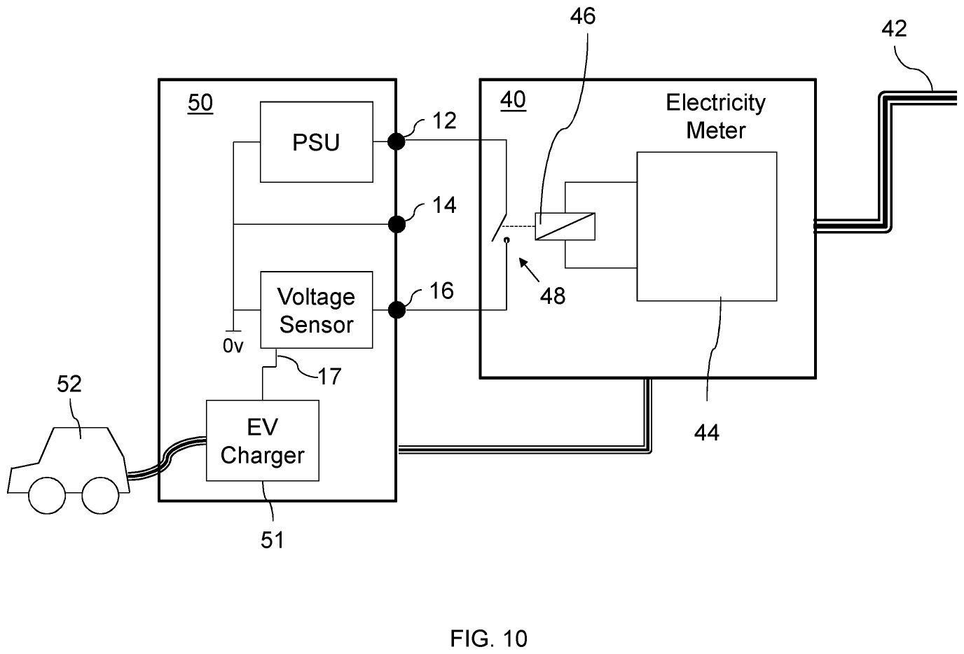

FIG. 10 shows an example use case in which the voltage and continuity detector circuitry is integrated within an electric vehicle charger unit 50, where it is used to activate an EV charger 51 within the EV charger unit 50 to charge a car 52 when the differential pricing state of a residential electricity meter 40 is in a low-tariff state (e.g. at night).

The meter 40 receives a mains supply 42 from the utility provider and also receives a signal (e.g. by radio or over a wire in the supply 42) for switching to a low-tariff rate. In this example, the meter 40 contains circuitry 44 for controlling a relay 46 to open or close a dry-contact switch 48 within the meter 40, depending on whether or not the low-tariff rate is inactive or active. The state of the switch 48 can be sensed through a pair of terminals in the meter 40. An electrician can connect a two-wire lead between the meter 40 and the power-output terminal 12 and sensing-input terminal 16 of the charger unit 50.

However, in other installations the meter 40 might instead provide a 240V AC wet-contact voltage signal when the low-tariff rate is active, and zero volts when it is inactive. In this case, the two-wire lead would connect between the meter 40 and the reference-voltage terminal 14 and sensing-input terminal 16 of the charger unit 50.

If the charger unit 50 incorporated two-terminal detector circuitry instead of a three-terminal detector, the lead from the meter 40 to the charger unit 50 could be terminated at the charger unit 50 end with the appropriate type of plug 30, 32, depending on whether the meter 40 outputs a dry- or wet-contact signal. This can ensure the charger unit 50 is not damaged by the car owner inadvertently reconfiguring the charger unit 50 to sense for the wrong type of contact.

When arranged for continuity (i.e. dry-contact) detection, the PSU 4 outputs an Extra Low Voltage (ELV) (e.g. 24V DC), which is safer than mains (e.g. 120V or 240V), but sufficiently high to overcome typical loses in the connection wiring and to work with dry contacts that won't necessarily operate under very low voltages.

It will be appreciated that the use of the detector 2 for sensing an electricity meter, and for controlling domestic electricity consumption responsive to this, is only one of many possible uses for a voltage and continuity detector as disclosed herein.

In some embodiments, the input voltage range may be adjustable for higher voltages, and the input may be adjusted to support current detection (e.g. via current transformers).

More generally, it will be appreciated by those skilled in the art that the invention has been illustrated by describing one or more specific embodiments thereof, but is not limited to these embodiments; many variations and modifications are possible, within the scope of the accompanying claims.

What is claimed is:

1. Voltage and continuity detection circuitry comprising:
a set of terminals for electrically coupling the detection circuitry to an independent electrical apparatus, wherein the set of terminals comprises a sensing-input terminal and further comprises a power-output terminal and a reference-voltage terminal, wherein the power-output terminal and the reference-voltage terminal may be two distinct terminals or one combined terminal;
a power supply unit for supplying electrical current from the power-output terminal; and
a voltage sensor for detecting a potential difference between the sensing-input terminal and a reference voltage,
wherein:
the voltage and continuity detection circuitry supports a voltage-detection mode of operation in which the voltage and continuity detection circuitry is configured to use the voltage sensor to detect a voltage supplied by the independent electrical apparatus by determining the presence or absence of a potential difference between the sensing-input terminal and the reference-voltage terminal;
the detection circuitry additionally supports a continuity-detection mode of operation in which the voltage and continuity detection circuitry is configured to use the voltage sensor to detect continuity in the independent electrical apparatus by determining the presence or absence of a potential difference between the sensing-input terminal and the power-output terminal; and
the voltage sensor comprises a binary digital output and is configured, in each mode of operation, to output a binary signal from the binary digital output indicative of whether the respective potential difference is determined to be present or absent.

2. The voltage and continuity detection circuitry of claim 1, wherein the power-output terminal and the reference-voltage terminal are two distinct terminals, wherein the power-output terminal is permanently electrically connected to the power supply unit and the reference-voltage terminal is permanently electrically connected to a reference voltage line within the detection circuitry.

3. The voltage and continuity detection circuitry of claim 1, wherein the power-output terminal and the reference-voltage terminal are provided as a combined power-output and reference-voltage terminal, and wherein the detection circuitry comprises a switch that is moveable between a first state in which the power supply unit is not electrically connected to the combined power-output and reference-voltage terminal, and a second state in which the power supply unit is electrically connected to the combined power-output and reference-voltage terminal; optionally wherein the detection circuitry is configured for the voltage-detection mode of operation when the switch is in the first state, and for the continuity-detection mode of operation when the switch is in the second state.

4. (canceled)

5. The voltage and continuity detection circuitry of claim 3, wherein the detection circuitry is configured such that the combined power-output and reference-voltage terminal is electrically connected to a reference voltage line within the detection circuitry when the switch is in the first state, and is not electrically connected to the reference voltage line when the switch is in the second state.

6. The voltage and continuity detection circuitry of claim 3, wherein the switch is arranged for mechanical actuation.

7. The voltage and continuity detection circuitry of claim 6, wherein the switch is arranged for actuation by a mechanical feature of a plug, wherein the switch is arranged to be in the first state when a plug having the mechanical feature is coupled to a terminal of the set of terminals and to be in the second state when a plug not having the mechanical feature is coupled to the terminal.

8. (canceled)

9. The voltage and continuity detection circuitry of claim 7, wherein the power supply unit is arranged to output direct current (DC) from the power-output terminal.

10. The voltage and continuity detection circuitry of claim 1, wherein the power supply unit is configured to receive alternating-current (AC) power.

11. The voltage and continuity detection circuitry of claim 1, wherein the power supply unit is arranged to receive power from an electrical power source and to output current from the power-output terminal, and wherein the power supply unit comprises an isolator for providing an isolated power supply for the power-output terminal that is galvanically isolated from the electrical power source.

12. The voltage and continuity detection circuitry of claim 11, arranged to power at least part of the voltage sensor from the isolated power supply.

13. (canceled)

14. The voltage and continuity detection circuitry of claim 1, wherein the detection circuitry is configured to prevent current from flowing into the detection circuitry through the power-output terminal.

15. The voltage and continuity detection circuitry of claim 1, wherein the detection circuitry is configured to attenuate current from flowing through the power-output terminal when an attenuation condition is met.

16. The voltage and continuity detection circuitry of claim 1, comprising a positive temperature coefficient (PTC) device arranged to varyingly attenuate current from flowing through the power-output terminal.

17. The voltage and continuity detection circuitry of claim 1, wherein the voltage sensor comprises a digital isolator for galvanically isolating the binary digital output from the sensing-input terminal.

18. The voltage and continuity detection circuitry of claim 1, wherein the voltage sensor is configured for rectifying an input voltage at the sensing-input terminal and for reducing the input voltage to a lower level when the input voltage is above a threshold level.

19. The voltage and continuity detection circuitry of claim 1, wherein the voltage sensor is configured to detect DC voltages of at least up to 350V and to detect AC voltages of at least up to 230V.

20. An electrical apparatus comprising a housing containing voltage and continuity detection circuitry as claimed in claim 1, and wherein the set of terminals are provided on a face of the housing or in a socket of the apparatus.

21. An electrical apparatus comprising voltage and continuity detection circuitry as claimed in claim 1, and further comprising an appliance, wherein the binary digital output is arranged to control an operation of the appliance.

22. The electrical apparatus of claim 21, wherein the appliance comprises electric vehicle supply equipment that is arranged to control charging of an electric vehicle in dependence on the binary digital output.

23. The electrical apparatus of claim 21, wherein the appliance comprises a home energy storage system, and wherein the electrical apparatus is configured to use the binary output to adjust a supply of electrical power to the home energy storage system in dependence on the binary digital output.
